(19) United States
(12) Patent Application Publication
(10) Pub. No.: US 2025/0311253 A1
(43) Pub. Date: Oct. 2, 2025

(54) STRUCTURES INCLUDING METAL-INSULATOR-METAL (MIM) CAPACITORS WITH VOIDS

(71) Applicant: GlobalFoundries Singapore Pte. Ltd., Singapore (SG)

(72) Inventors: EE JAN KHOR, Singapore (SG); WANBING YI, Singapore (SG)

(21) Appl. No.: 18/624,085

(22) Filed: Apr. 1, 2024

(51) Int. Cl. H01L 21/311; H01L 21/3213

(52) U.S. Cl. CPC H10D 1/692; H01L 21/31144; H01L 21/32139

(57) ABSTRACT

The embodiments herein relate to structures of MIM capacitors including a sealed void and methods of forming the same. According to an aspect of the present disclosure, a structure is provided. The structure includes a MIM capacitor having a first electrode and a second electrode over the first electrode. A conductive via is laterally adjacent to the second electrode and electrically connected to the first electrode. A void extends around an outer perimeter of the second electrode.

### TECHNICAL FIELD

The present disclosure relates generally to semiconductor devices and, more particularly, to structures that include a MIM capacitor with a void and methods of forming the same.

### BACKGROUND

On-chip passive elements, such as metal-insulator-metal (MIM) capacitors, are deployed in many types of integrated circuits, such as radiofrequency integrated circuits. A MIM capacitor may be integrated into one or more of the metallization levels of a back-end-of-line (BEOL) interconnect structure. A two-electrode MIM capacitor includes two conductive plates, which operate as electrodes, and a capacitor dielectric disposed between the conductive plates as an electrical insulator. The capacitance, or amount of charge held by the MIM capacitor per unit of applied voltage, depends among other factors on the area of the top and bottom conductive plates, their separation, and the dielectric constant of the material constituting the capacitor dielectric.

Improved methods for fabricating structures that include a MIM capacitor with a void and structures that include a MIM capacitor with a sealed void are needed.

### SUMMARY

To achieve the foregoing and other aspects of the present disclosure, a MIM capacitor with a void and methods of forming the same are presented.

According to an aspect of the present disclosure, a structure is provided. The structure includes a MIM capacitor having a first electrode and a second electrode over the first electrode. A conductive via is laterally adjacent to the second electrode and electrically connected to the first electrode. A void extends about an outer perimeter of the second electrode.

According to another aspect of the present disclosure, a method of forming a structure is provided. The method includes forming a MIM capacitor having a first electrode and a second electrode over the first electrode and forming a conductive via laterally adjacent to the first electrode and electrically connected to the first electrode. A void is formed extending about an outer perimeter of the second electrode.

### BRIEF DESCRIPTION OF THE DRAWINGS

The embodiments of the present disclosure will be better understood from a reading of the following detailed description, taken in conjunction with the accompanying drawings:

FIGS. 1-6 are cross-sectional views of a structure at successive fabrication stages of a processing method, according to an embodiment of the disclosure.

FIG. 2A is a top view of the structure in which FIG. 2 is taken generally along line 2-2, according to an embodiment of the disclosure.

FIG. 3A is a top view of the structure in which FIG. 3 is taken generally along line 3-3, according to an embodiment of the disclosure.

FIG. 5A is a top view of the structure in which FIG. 5 is taken generally along line 5-5, according to an embodiment of the disclosure.

FIG. 6A is a cross-sectional view of an enlarged portion of the structure in FIG. 6, according to an embodiment of the disclosure.

For simplicity and clarity of illustration, the drawings illustrate the general manner of construction, and certain descriptions and details of well-known features and techniques may be omitted to avoid unnecessarily obscuring the discussion of the described embodiments of the disclosure.

Additionally, features in the drawings are not necessarily drawn to scale. For example, the dimensions of some of the features in the drawings may be exaggerated relative to other features to help improve the understanding of the embodiments of the device. The same reference numerals in different drawings denote the same features, while similar reference numerals may, but do not necessarily, denote similar features.

### DETAILED DESCRIPTION

The present disclosure relates to structures including a MIM capacitor with a void and methods of forming the same. Various embodiments of the present disclosure are now described in detail with accompanying drawings. It is noted that like and corresponding features are referred to by the use of the same reference numerals. The embodiments disclosed herein are exemplary, and not intended to be exhaustive or limiting to the disclosure.

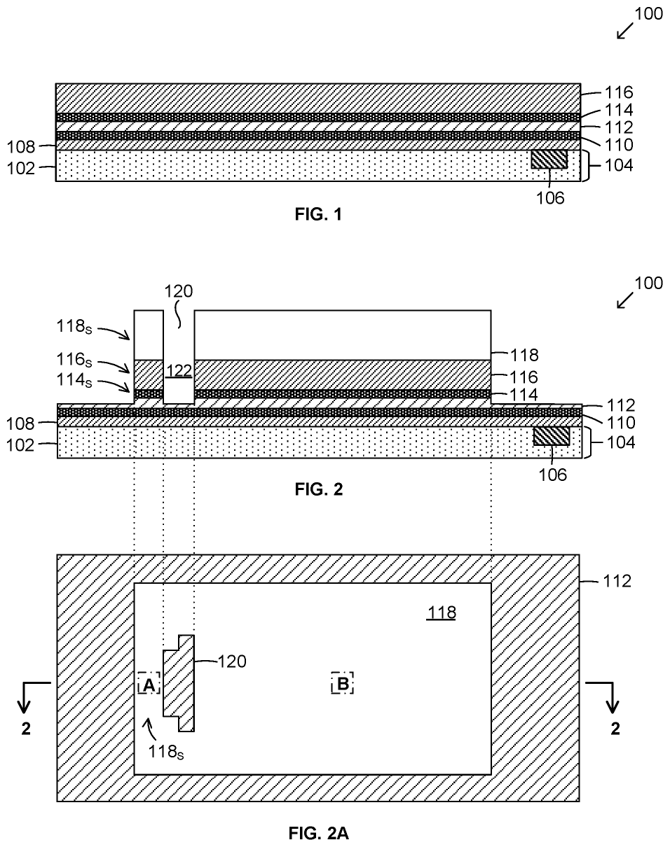

FIG. 1 is a cross-sectional view of a structure 100, according to an embodiment of the disclosure. The structure 100 may be part of a back-end-of-line (BEOL) structure of a semiconductor device and may include an interlayer dielectric 102 of a metallization level 104, a wiring feature 106 in the interlayer dielectric 102, and a capping layer 108 on the interlayer dielectric 102 and the wiring feature 106. The wiring feature 106 may be, for example, a conductive line. The capping layer 108 may at least protect the wiring feature 106 from oxidation and/or subsequent processes. The structure 100 is carried over a front-end-of-line (FEOL) structure (not shown) of the semiconductor device that may include active electronic components, such as transistors or diodes. The FEOL structure and the BEOL structure of the semiconductor device are on a substrate (not shown). Additional metallization levels (not shown) may exist between the metallization level 104 and the FEOL structure.

The interlayer dielectric 102 may include an electrically insulative material, such as silicon dioxide, carbon-doped silicon oxide, tetraethoxysilane (TEOS), borophosphosilicate glass (BPSG), or undoped silicate glass (USG). The wiring feature 106 may include a metallic material, such as copper, aluminum, or a combination thereof. The capping layer 108 may include a nitride-based electrically insulative material, such as silicon nitride or titanium nitride.

A bottom conductor layer 110, an insulator layer 112, a top conductor layer 114, and a dielectric layer 116 may be sequentially formed over the capping layer 108; the bottom conductor layer 110, the insulator layer 112, and the top conductor layer 114 may be subsequently used to form a metal-insulator-metal (MIM) capacitor, including a bottom electrode, a capacitor insulator, and a top electrode, respectively. The dielectric layer 116 may have a sufficient thickness to at least protect the underlying top conductor layer 114 from subsequent processes during the fabrication of the MIM capacitor.

The bottom conductor layer 110 and the top conductor layer 114 may include an electrically conductive material, such as titanium, titanium nitride, tantalum, tantalum nitride, tungsten, tungsten nitride, or a combination thereof, though not necessarily the same material for the bottom conductor layer 110 and the top conductor layer 114. The bottom conductor layer 110 and the top conductor layer 114 may be formed using a deposition technique, including a chemical vapor deposition (CVD) process or a physical vapor deposition (PVD) process. The insulator layer 112 may include a dielectric material, such as silicon dioxide or a dielectric material having a dielectric constant (i.e., permittivity) higher than silicon dioxide, commonly referred to as a high-k dielectric material. Examples of a high-k dielectric material may include hafnium oxide or aluminum oxide. The insulator layer 112 may be formed using a deposition technique, including a CVD process. The dielectric layer 116 may include an electrically insulative material, such as silicon nitride. The dielectric layer 116 may be formed using a deposition technique, including a CVD process. In an embodiment of the disclosure, the dielectric layer 116 may have a thickness greater than the collective thickness of the bottom conductor layer 110, the top conductor layer 114, and the insulator layer 112.

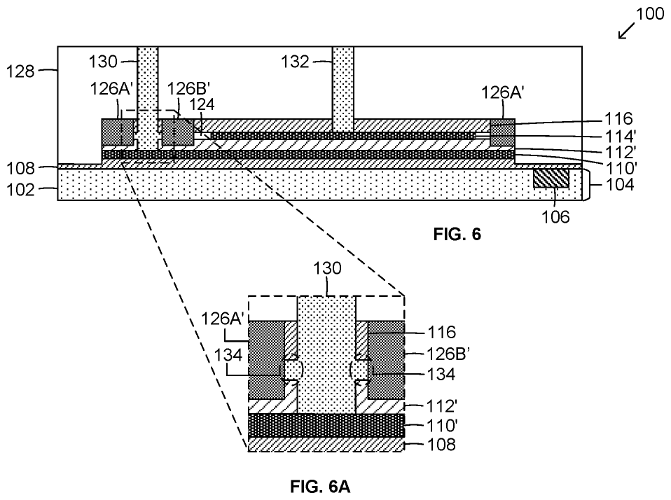

FIG. 2 is a cross-sectional view of the structure 100 at a fabrication stage subsequent to FIG. 1 and FIG. 2A is an exemplary top view of the structure 100 in which FIG. 2 is taken generally along line 2-2, according to an embodiment of the disclosure. FIG. 2A further denotes designated locations A, B for conductive vias, outlined in dash-dot lines, that will be subsequently formed and used for the operation of the MIM capacitor (see FIG. 6). For example, conductive vias formed in locations A, B may provide electrical connectivity to the bottom electrode and the top electrode, respectively.

A mask 118 may be formed on an upper surface of the dielectric layer 116. The term “mask” may refer to a layer of patterned material applied over an underlying layer of material that includes openings, or patterns, that allow for selective processing of the underlying layer. The mask 118 may include a photoresist or a nitride-containing material deposited using a deposition technique, such as a spin-coating process or a CVD process. The mask 118 may include a mask opening 120 near an edge of the mask 118, such that a strip area 118s may be formed between the edge of the mask 118 and the mask opening 120. The designated location A of a conductive via may be arranged on the strip area 118s. The strip area 118s may have an elongated shape and may have a length along the edge of the mask 118. In an embodiment of the disclosure, the length of the strip area 118s may be longer than the width taken perpendicular thereto. It may be understood that the mask opening 120 illustrated in FIG. 2A is only exemplary, and the mask 118 may include any number of mask opening(s) in various geometric configurations according to design requirements.

The dielectric layer 116 and the top conductor layer 114 may be patterned through the mask 118 using a material removal technique, including an etching process. The material removal technique may be a single-step or a multi-step process. An opening 122 may be formed in a section of the dielectric layer 116 and the top conductor layer 114 unmasked by the mask 118. Surrounding areas unmasked by the mask 118 may also be removed in the process. The opening 122 may at least extend through the dielectric layer 116 and the top conductor layer 114, and a portion of the insulator layer 112 may be exposed in the opening 122. As a result of forming the opening 122, a dielectric strip area 116s may be formed adjacent to the edge of the dielectric layer 116, and a conductor strip area 114s may be formed adjacent to the edge of the top conductor layer 114. Side surfaces of the dielectric layer 116 and the top conductor layer 114 may be exposed in at least the opening 122, and the side surfaces may be substantially coplanar with each other. The opening 122 may, additionally or optionally, extend partially into the insulator layer 112.

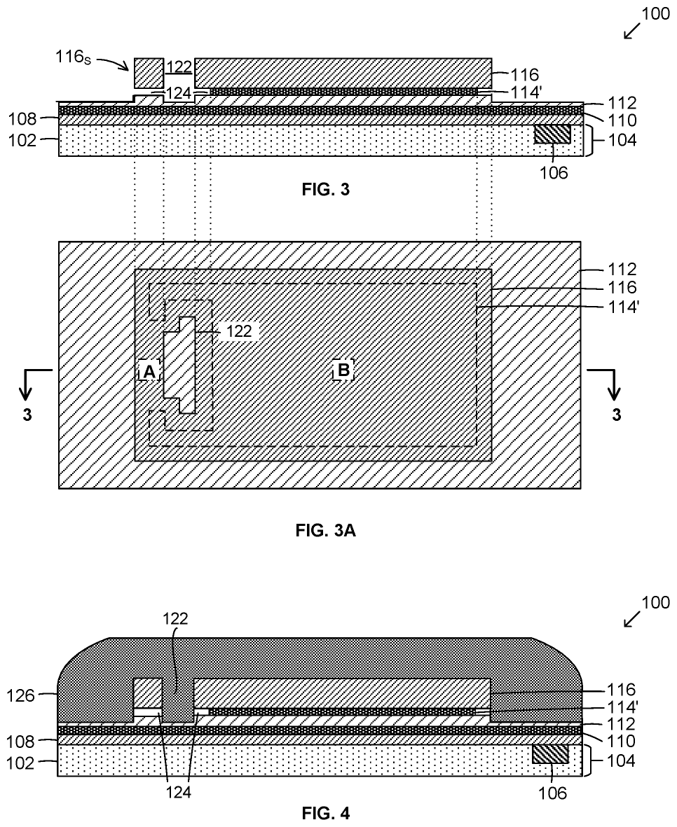

FIG. 3 is a cross-sectional view of the structure 100 at a fabrication stage subsequent to FIG. 2 and FIG. 3A is an exemplary top view of the structure 100 in which FIG. 3 is taken generally along line 3-3, according to an embodiment of the disclosure. The mask 118 may be removed once the patterning of the dielectric layer 116 and the top conductor layer 114 is completed.

A top electrode 114′ of the MIM capacitor may be formed from the top conductor layer 114 and the top electrode 114′ is shown by a dashed line in FIG. 3A. The top electrode 114′ may be formed by a material removal technique, including an etching process, to remove a portion of the top conductor layer 114. The top conductor layer 114 may be recessed laterally from the exposed side surfaces, relative to the bottom conductor layer 110 to form a void 124 vertically between the dielectric layer 116 and the bottom conductor layer 110. The material removal technique may remove a portion of the top conductor layer 114 selective to the dielectric layer 116 and the insulator layer 112 such that the dielectric layer 116 and the insulator layer 112 may remain predominantly intact during the recessing of the top conductor layer 114. The void 124 may be laterally offset from the opening 122 and extends about an outer perimeter, or boundary, of the top electrode 114′. As illustrated in FIG. 3A, the top conductor layer 114 may be completely removed in the conductor strip area 114s where the designated location A of a conductive via is located. This results from the void 124 extending from opposite side surfaces of the dielectric layer 116 and merging under the dielectric strip area 116s.

FIG. 4 is a cross-sectional view of the structure 100 at a fabrication stage subsequent to FIG. 3, according to an embodiment of the disclosure. A spacer material 126 may be formed over the structure 100 using a deposition technique, including a CVD process. The spacer material 126 may include an electrically insulative dielectric material, such as silicon nitride. In this embodiment, the employed deposition technique may be non-conformal such that the spacer material 126 may fill the opening 122 and not the void 124, thereby sealing off the void 124 to form a sealed void 124. For example, the sealed void 124 may be collectively surrounded by the dielectric layer 116 from above, the insulator layer 112 from below, and laterally by the spacer material 126 and/or the top electrode 114′.

The sealed void 124 may include different gases where no solid material is present. Any number of gases may be present in the sealed void 124. Alternatively, the employed deposition technique may be conformal such that the spacer material 126 fills the openings 122 and the void 124, even though this embodiment is not illustrated in the accompanying drawings.

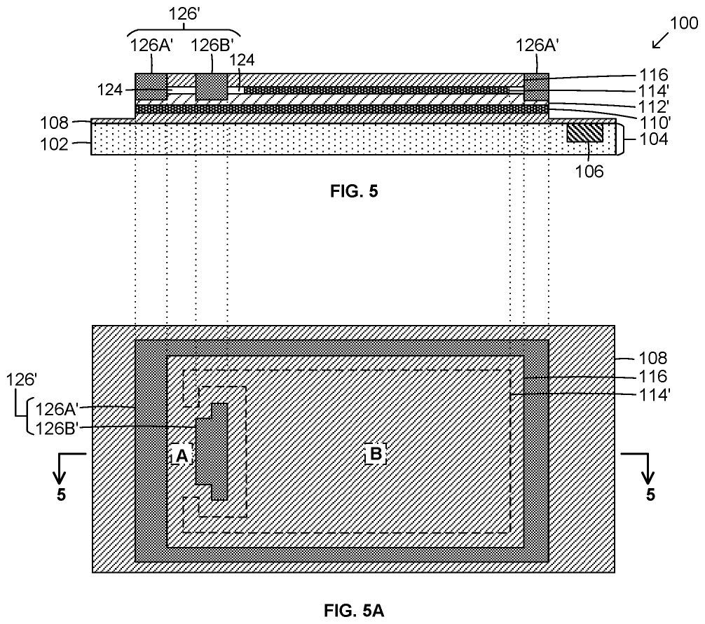

FIG. 5 is a cross-sectional view of the structure 100 at a fabrication stage subsequent to FIG. 4 and FIG. 5A is an exemplary top view of the structure 100 in which FIG. 5 is taken generally along line 5-5, according to an embodiment of the disclosure. A spacer 126′ may be formed from the spacer material 126 by a material removal technique, including a blanket etching process. Blanket etching is a process in which a layer of material is removed uniformly from a surface, typically without the use of a mask or patterning layer. The material removal technique may be a single-step or a multi-step process.

During the material removal technique, portions of the insulator layer 112 and the bottom conductor layer 110 may be removed, thereby forming a capacitor insulator 112′ and a bottom electrode 110′, respectively. The bottom electrode 110′ may have a larger upper surface area than a bottom surface area of the top electrode 114′. For example, the bottom electrode 110′ may include an outer perimeter, or boundary, that extends beyond the outer perimeter of the top electrode 114′. Additionally, a portion of the dielectric layer 116 may also be removed due to the similarity in material composition to the insulator layer 112. A portion of the capping layer 108 may, additionally or optionally, be removed in the process, leaving at least a portion on the interlayer dielectric 102 and the wiring feature 106. In an embodiment of the disclosure, the upper surface of the spacer 126′ may be substantially coplanar with the upper surface of the dielectric layer 116.

The spacer 126′ may extend vertically from the capacitor insulator 112′ to the upper surface of the dielectric layer 116. The spacer 126′ may laterally contact the dielectric layer 116 on at least one side surface. For example, the spacer 126′ may include a first spacer component 126A′ and a second spacer component 126B′. The first spacer component 126A′ may laterally surround the dielectric layer 116 about an outer perimeter, or boundary, and contact the dielectric layer 116 at an inner side surface of the first spacer component 126A′. The first spacer component 126A′ may further include an outer side surface that may be substantially coplanar with a side surface of the bottom electrode 110′. The second spacer component 126B′ may be encircled by the first spacer component 126A′ and may include side surfaces in contact with the dielectric layer 116. The second spacer component 126B′ may also be laterally spaced from the top electrode 114′ by the sealed void 124. The strip area, where the designated location A of a conductive via is located, may be laterally between a section of the first spacer component 126A′ and a section of the second spacer component 126B′.

FIG. 6 is a cross-sectional view of the structure 100 at a fabrication stage subsequent to FIG. 5, according to an embodiment of the disclosure. An interlayer dielectric 128 may be formed over the structure 100 using a deposition technique, including a CVD process. The interlayer dielectric 128 may include an electrically insulative material, such as silicon dioxide, carbon-doped silicon oxide, tetraethoxysilane (TEOS), borophosphosilicate glass (BPSG), or undoped silicate glass (USG), though not necessarily the same material as the interlayer dielectric 102.

Conductive vias 130, 132 may be formed in the interlayer dielectric 128 at the designated locations A, B, respectively. The conductive via 130 may be laterally adjacent to the top electrode 114′ and may extend through the interlayer dielectric 128, the dielectric layer 116, the sealed void 124, and the capacitor insulator 112′ to be electrically connected to the bottom electrode 110′. Likewise, the conductive via 130 may be over the top electrode 114′ and may extend through the dielectric layer 116 to be electrically connected to the top electrode 114′.

The conductive vias 130, 132 may be formed using a patterning technique, including photolithography and etching processes, to define via openings (not shown) in the interlayer dielectric 128 and filling the via openings using a deposition technique, including an electrochemical deposition process such as electroplating or electroless plating. The conductive vias 130, 132 may include a metallic material, including copper, aluminum, or an alloy thereof.

As the designated location A for the conductive via 130 is placed on the strip area, the strip area may assist in removing the top conductor layer 114 completely during the recessing process to form the void 124 and the top electrode 114′. This would advantageously enable the via opening of the conductive via 130 to be formed in a single process step, rather than a multi-step process, due to the similar material compositions of the dielectric layer 116 and the capacitor insulator 112′.

FIG. 6A is a cross-sectional view of an enlarged portion of the structure 100, according to an embodiment of the disclosure. In particular, the conductive via 130 may include protrusions 134 at opposite side surfaces of the conductive via 130, such that each of the protrusions 134 may extend towards the first spacer component 126A′ and the second spacer component 126B′. The protrusions 134 may further contact the first spacer component 126A′ and the second spacer component 126B′. The protrusions 134 may occupy the sealed void 124 between the first spacer component 126A′ and the second spacer component 126B′. The protrusions 134 may be present when the conductive via 130 has a narrower dimension, such as a width, than the sealed void 124.

As presented above, structures including a MIM capacitor with a sealed void and methods of forming the same are presented. The MIM capacitor may include a top electrode, a substantially parallel bottom electrode, and a capacitor insulator between the top and bottom electrodes. The top electrode may have a smaller bottom surface area than an upper surface area of the bottom electrode. For example, the top electrode may include an outer perimeter, or boundary, within an outer perimeter, or boundary, of the bottom electrode. The sealed void may extend around an outer perimeter, or boundary, of the top electrode, and remains within the outer perimeter of the bottom electrode. Conductive vias may provide electrical connectivity to the top electrode and the bottom electrode of the MIM capacitor. The conductive via electrically coupling the bottom electrode may be laterally adjacent to the top electrode by a spacer, and the spacer may be arranged laterally from the top electrode by the sealed void.

The processing method of forming the MIM capacitor uses a single mask. For example, a first conductor layer may be deposited, a second conductor layer may be deposited over the first conductor layer, and a dielectric layer may be deposited on the second conductor layer. The mask may be used to form an opening at least through the dielectric layer and the second conductor layer, and the second conductor layer may be recessed relative to the first conductor layer to define a void that is offset laterally from the opening to form the second electrode.

The first electrode may be formed by a blanket etching process. For example, a spacer material may be deposited over the first conductor layer to at least fill the opening to seal the void laterally between the spacer material and the second electrode. A spacer may be formed from the spacer material having an upper surface coplanar with an upper surface of the dielectric layer using the blanket etching process. Additionally, the first electrode may be formed in the process. By using a single mask to form the MIM capacitor, a greater cost advantage to the fabrication process may be achieved.

The terms “top”, “bottom”, “over”, “under”, and the like in the description and the claims, if any, are used for descriptive purposes and not necessarily for describing permanent relative positions. It is to be understood that the terms so used are interchangeable under appropriate circumstances such that the embodiments of the devices described herein are, for example, capable of operation in other orientations than those illustrated or otherwise described herein.

Additionally, the formation of a first feature over or on a second feature in the description that follows may include embodiments in which the first and second features are formed in direct contact, and may also include embodiments in which additional features may be formed by interposing the first and second features, such that the first and second features may not be in direct contact.

Similarly, if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of features is not necessarily limited to those features but may include other features not expressly listed or inherent to such process, method, article, or device. Occurrences of the phrase “in an embodiment” herein do not necessarily all refer to the same embodiment.

In addition, unless otherwise indicated, all numbers expressing quantities, ratios, and numerical properties of materials, reaction conditions, and so forth used in the specification and claims are to be understood as being modified in all instances by the term “about”.

Furthermore, approximating language, as used herein throughout the specification and claims, may be applied to modify any quantitative representation that could permissibly vary without resulting in a change in the basic function to which it is related. Accordingly, a value modified by a term or terms, such as “approximately”, “about,” or “substantially” is not limited to the precise value specified. In some instances, the approximating language may correspond to the precision of an instrument for measuring the value. In other instances, the approximating language may correspond to within normal tolerances of the semiconductor industry. For example, “substantially coplanar” means substantially in a same plane within normal tolerances of the semiconductor industry, and “substantially perpendicular” means at an angle of 90 degrees plus or minus a normal tolerance of the semiconductor industry.

While several exemplary embodiments have been presented in the above-detailed description of the device, it should be appreciated that a number of variations exist. It should further be appreciated that the embodiments are only examples, and are not intended to limit the scope, applicability, dimensions, or configuration of the device in any way. Rather, the above-detailed description will provide those skilled in the art with a convenient road map for implementing an exemplary embodiment of the device, it is understood that various changes may be made in the function and arrangement of features and methods of fabrication described in an exemplary embodiment without departing from the scope of this disclosure as set forth in the appended claims.

What is claimed is:

1. A structure, comprising:
a metal-insulator-metal (MIM) capacitor including a first electrode and a second electrode over the first electrode;
a conductive via laterally adjacent to the second electrode and electrically connected to the first electrode; and
a void extends around an outer perimeter of the second electrode.

2. The structure of claim 1, wherein the first electrode comprises an outer perimeter, and the outer perimeter of the second electrode is within the outer perimeter of the first electrode.

3. The structure of claim 2, wherein the void is laterally between the conductive via and the second electrode.

4. The structure of claim 3, wherein the void is within the outer perimeter of the first electrode.

5. The structure of claim 1, wherein the MIM capacitor further comprises a capacitor insulator between the first electrode and the second electrode, further comprising a dielectric layer on the second electrode, wherein the void is surrounded by the dielectric layer from above and the capacitor insulator from below.

6. The structure of claim 5, further comprising a first spacer component, and the first spacer component is laterally between the conductive via and the void.

7. The structure of claim 6, further comprising a second spacer component laterally surrounding the first spacer component and the first electrode.

8. The structure of claim 7, wherein the second spacer component includes an outer side surface coplanar with a side surface of the first electrode.

9. The structure of claim 8, wherein the first spacer component has an upper surface, the second spacer component has an upper surface, and the dielectric layer has an upper surface, wherein the upper surfaces of the first spacer component and the second spacer component are coplanar with the upper surface of the dielectric layer.

10. The structure of claim 8, wherein the conductive via includes a first protrusion, and the first protrusion extends towards the second electrode.

11. The structure of claim 10, wherein the first protrusion laterally contacts the first spacer component.

12. The structure of claim 11, wherein the conductive via further comprises a second protrusion at an opposite side of the first protrusion, and the second protrusion laterally contacts the second spacer component.

13. A method, comprising:
forming a metal-insulator-metal (MIM) capacitor including a first electrode and a second electrode over the first electrode;
forming a conductive via laterally adjacent to the first electrode and electrically connected to the first electrode; and
forming a void extending around an outer perimeter of the second electrode.

14. The method of claim 13, wherein the first electrode comprises an upper surface area and the second electrode comprises a bottom surface area that is smaller than the upper surface area of the first electrode.

15. The method of claim 13, wherein forming the MIM capacitor comprises using a single mask.

16. The method of claim 15, further comprising:
depositing a first conductor layer;
depositing a second conductor layer over the first conductor layer,
depositing a dielectric layer on the second conductor layer;
using the mask to form an opening at least through the dielectric layer and the second conductor layer; and
recessing the second conductor layer relative to the first conductor layer to define a void that is offset laterally from the opening to form the second electrode.

17. The method of claim 16, further comprising depositing a spacer material over the first conductor layer and filling the opening to seal the void laterally between the spacer material and the second electrode.

18. The method of claim 17, further comprising forming a spacer from the spacer material having an upper surface coplanar with an upper surface of the dielectric layer.

19. The method of claim 18, wherein the forming of coplanar upper surfaces of the spacer and the dielectric layer also forms the first electrode of the MIM capacitor.

20. The method of claim 19, wherein the forming of the first electrode of the MIM capacitor uses a blanket etching process.
